(19) United States
(12) Patent Application Publication
(10) Pub. No.: US 2018/0095117 A1
(43) Pub. Date: Apr. 5, 2018

(54) SIGNAL DETECTING METHOD AND SIGNAL DETECTING SYSTEM

(71) Applicant: SENAO NETWORKS, INC., Taoyuan City (TW)

(72) Inventor: MIN-HUNG TSAI, Taoyuan City (TW)

(21) Appl. No.: 15/283,443

(22) Filed: Oct. 2, 2016

(51) Int. Cl. G01R 21/133; G01R 23/16

(52) U.S. Cl. CPC G01R 21/133; G01R 23/16

(57) ABSTRACT

A signal detecting method includes operations as follows: receiving an input signal, and generating an energy signal according to the input signal; calculating average energy of each period of the energy signal according to the energy signal; calculating energy difference of each period of the energy signal according to the energy signal and the average energy of each period of the energy signal; and generating a signal detecting result according to the average energy and the energy difference of each period of the energy signal.

### BACKGROUND

### Field of Invention

The present disclosure relates to a signal processing method and a signal processing system. More particularly, the present disclosure relates to a signal detecting method and a signal detecting system.

### Description of Related Art

With the rapid advance of wireless communication technology, wireless communication devices, i.e., cellphones, digital phones and digital intercoms, are playing an increasingly important role in the lives of many people. Currently, after the wireless communication devices temporarily detect effective signals, e.g., frequency shift keying signals, the wireless communication device enter standby modes, so as to achieve a goal of saving power for the wireless communication devices. Therefore, the operation time of the wireless communication devices can be effectively enhanced.

However, when the wireless communication devices keep working on the standby modes, the wireless communication devices may fail to detect and receive the effective signals, so that quality of user experiences may be decreased. Although the accuracy of detecting the effective signals can be enhanced through a manner which increases a signal sample rate, a clock signal having higher frequency is necessary to support the increasing signal sample rate, thereby, the power consumption of the wireless communication devices are dramatically increasing.

Accordingly, a significant challenge is related to ways in which to detect the effective signals accurately while at the same time reducing the power consumption of the wireless communication devices associated with designing signal detecting methods and signal detecting systems.

### SUMMARY

An aspect of the present disclosure is directed to a signal detecting method. The signal detecting method comprises operations as follows: receiving an input signal, and generating an energy signal according to the input signal; calculating average energy of each period of the energy signal according to the energy signal; calculating energy difference of each period of the energy signal according to the energy signal and the average energy of each period of the energy signal; and generating a signal detecting result according to the average energy and the energy difference of each period of the energy signal.

Another aspect of the present disclosure is directed to a signal detecting system. The signal detecting system comprises an average energy calculating module, an energy difference calculating module and a detecting result calculating module, and the detecting result calculating module is electrically connected to the average energy calculating module and the energy difference calculating module. The average energy calculating module is configured to calculate average energy of each period of an energy signal according to the energy signal. The energy difference calculating module is configured to calculate energy difference of each period of the energy signal according to the energy signal and the average energy of each period of the energy signal. The detecting result calculating module is configured to generate a signal detecting result according to the average energy and the energy difference of each period of the energy signal.

It is to be understood that the foregoing general description and the following detailed description are by examples, and are intended to provide further explanation of the invention as claimed.

### BRIEF DESCRIPTION OF THE DRAWINGS

The present disclosure can be more fully understood by reading the following detailed description of the embodiment, with reference made to the accompanying drawings as follows:

FIG. 1 is a block schematic diagram of a signal detecting system according to some embodiments of the present disclosure;

FIG. 2A, 2B, 2C are operating schematic diagrams of the signal detecting system according to some embodiments of the present disclosure;

FIG. 2D is an operating schematic diagram of a detecting result calculating module of the signal detecting system according to some embodiments of the present disclosure; and

FIG. 3 is a flow chart of a signal detecting method according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

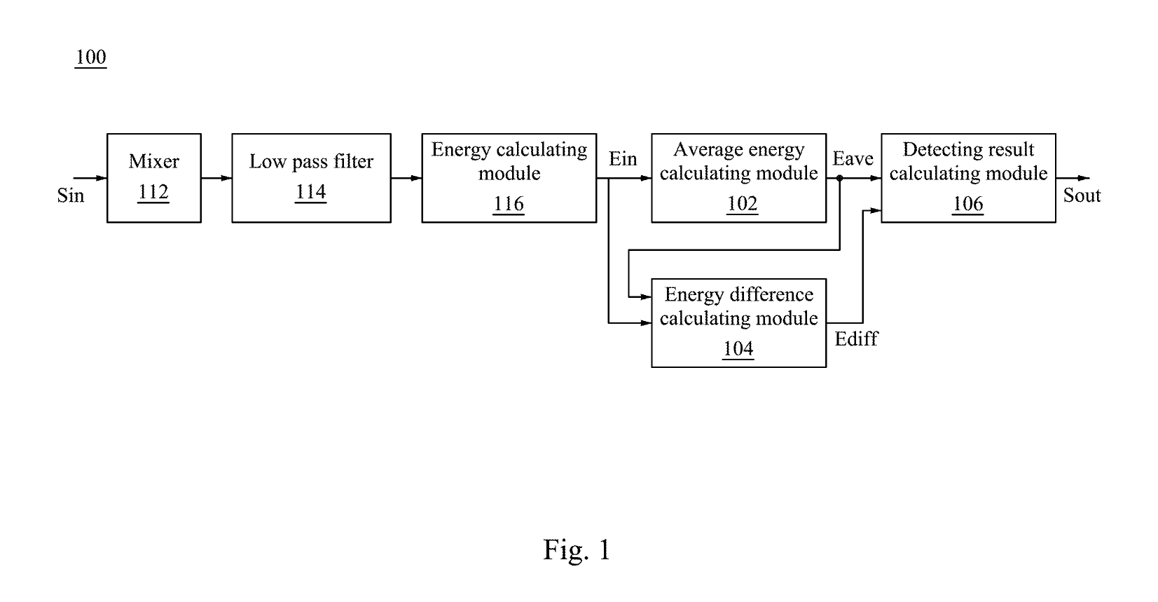

FIG. 1 is a block schematic diagram of a signal detecting system 100 according to some embodiments of the present disclosure. As show in FIG. 1, the signal detecting system 100 includes an average energy calculating module 102, an energy difference calculating module 104 and a detecting result calculating module 106. The energy difference calculating module 104 is electrically connected to the average energy calculating module 102, and the detecting result calculating module 106 is electrically connected to the average energy calculating module 102 and the energy difference calculating module 104.

The average energy calculating module 102 is configured to receive an energy signal Ein, and calculate average energy Eave of each period of the energy signal Ein. The energy difference calculating module 104 is configured to receive the energy signal Ein and the average energy Eave, and calculate energy difference Ediff of each period of the energy signal Ein according to the energy signal Ein and the average energy Eave of each period of the energy signal Ein. The detecting result calculating module 106 is configured to generate a signal detecting result Sout according to the average energy Eave and the energy difference Ediff of each period of the energy signal Ein.

In one embodiment, the average energy calculating module 102 calculates average energy Eave of each period of an energy signal Ein according to the equation (1) as follow:

$$Eave ( p ) = \frac{1}{BlockSize} {\sum }_{n = ( p - 1 ) * BlockSize}^{p * BlockSize - 1} Ein ( n ) \qquad ( 1 )$$

wherein Eave(p) denotes the pth average energy of the pth period of the energy signal Ein, BlockSize denotes the number of the samples of each period of the energy signal Ein, Ein(n) denotes an energy value of the nth samples of the energy signal Ein, and the initial value of the discrete number p is 1. In this embodiment, the number of the samples of each period of the energy signal Ein, i.e., BlockSize, is 128.

In another embodiment, the energy difference calculating module 104 calculates energy difference Ediff of each period of the energy signal Ein according to the equation (2) as follow:

$$Ediff ( q ) = {\sum }_{n = ( q - 1 ) * BlockSize}^{q * BlockSize - 1} \vert Ein ( n ) - Eave ( q - 1 ) \vert \qquad ( 2 )$$

wherein Ediff(q) denotes the qth energy difference of the qth period of the energy signal Ein, BlockSize denotes the number of the samples of each period of the energy signal Ein, Ein(n) denotes an energy value of the nth samples of the energy signal Ein, and the initial value of the discrete number q is 2. In this embodiment, the first energy difference Ediff(1) of the first period of the energy signal Ein is predetermined as 0, and the number of the samples of each period of the energy signal Ein, i.e., BlockSize, is 128.

In one embodiment, the detecting result calculating module 106 is configured to generate average signals and difference signals according to the average energy Eave and the energy difference Ediff of each period of the energy signal Ein, and to compare the average signals with the difference signals to generate the signal detecting result Sout.

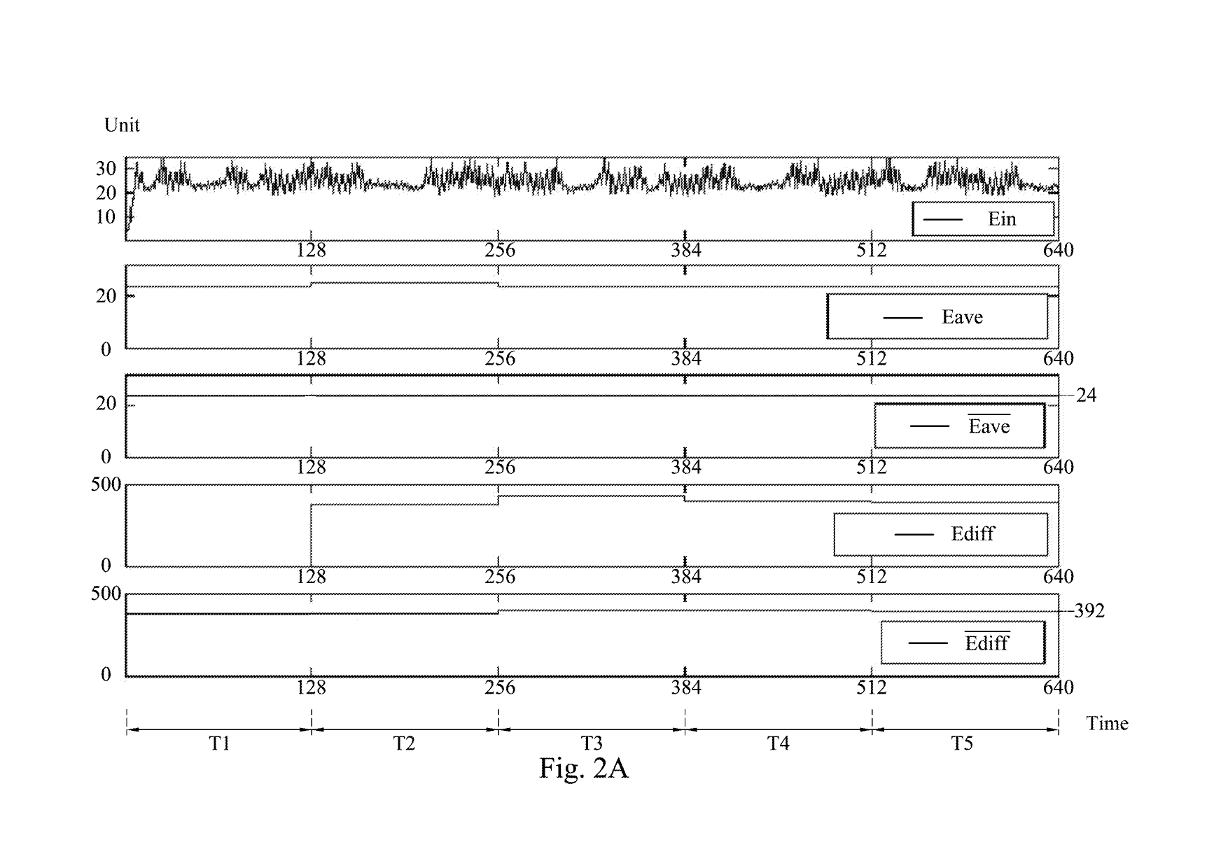

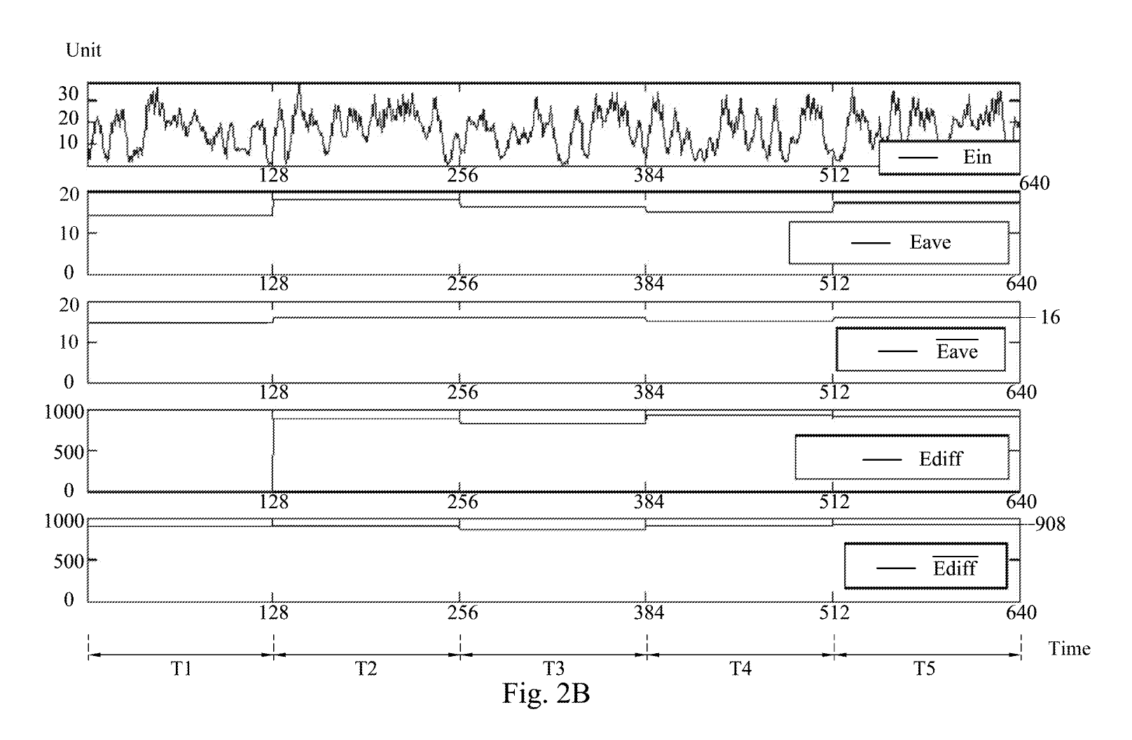

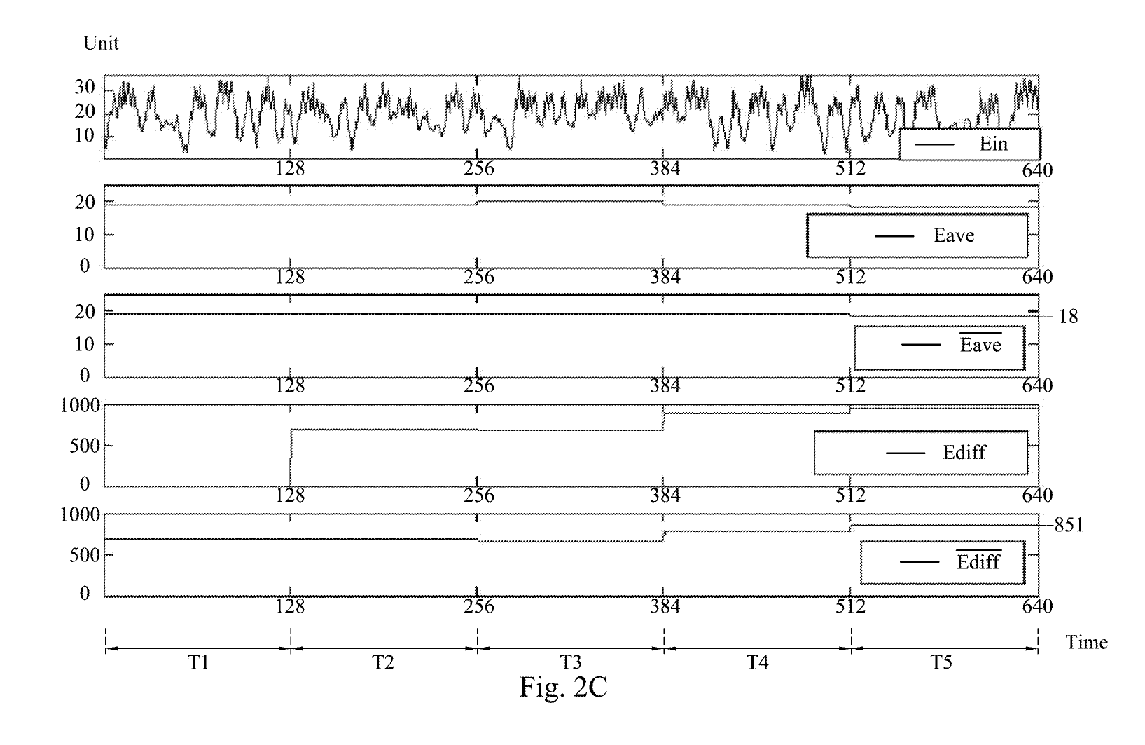

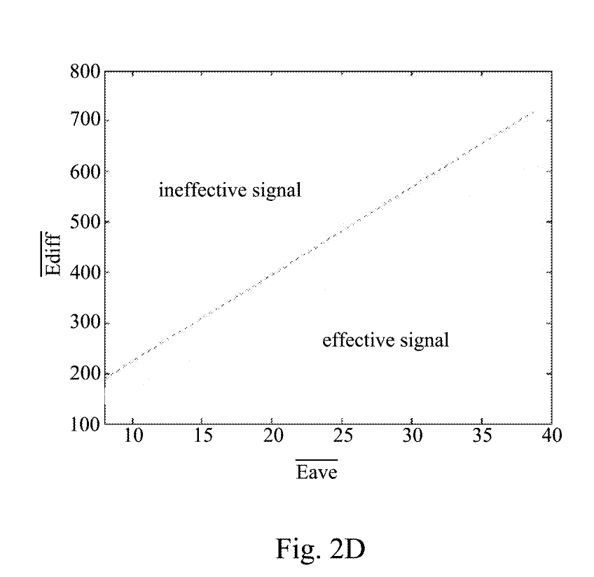

For facilitating the understanding of the signal detecting system 100 in FIG. 1, references are now made to FIGS. 2A, 2B and 2C, which are operating schematic diagrams of the signal detecting system 100 according to some embodiments of the present disclosure. In some embodiments, the average energy calculating module 102 is configured to calculate first average energy Eave(1) of a first period T1 of the energy signal Ein, second average energy Eave(2) of a second period T2 of the energy signal Ein and third average energy Eave(3) of a third period T3 of the energy signal Ein according to the energy signal Ein. In this embodiment, the second period T2 is adjacent to the first period T1, and the third period T3 is adjacent to the second period T2.

Subsequently, the detecting result calculating module 106 is configured to provide a first average signal, to generate a second average signal according to a first average signal and the second average energy Eave(2), and then to generate a third average signal according to the second average signal and the third average energy Eave(3). Furthermore, the first average signal is predetermined. In this embodiment, the detecting result calculating module 106 generates the second average signal and the third average signal according to the equation (3) as follow:

$$\overline{Eave} ( p + 1 ) = \frac{\overline{Eave} ( p ) + Eave ( p + 1 )}{2} \qquad ( 3 )$$

wherein E̅a̅v̅e̅(p+1) denotes the (p+1)th average signal, Eave(p+1) denotes the (p+1)th average energy of the (p+1)th period of the energy signal Ein, and the initial value of the discrete number p is 1. In this embodiment, the first average signal E̅a̅v̅e̅(1) is predetermined the same as the first average energy Eave(1) of the first period T1 of the energy signal Ein.

Referring to both FIGS. 1 and 2A, in further embodiment, the energy difference calculating module 104 is configured to calculate a second energy difference Ediff(2) of the second period T2 of the energy signal Ein according to the energy signal Ein and the first average energy Eave(1), and then to calculate a third energy difference Ediff(3) of the third period T3 of the energy signal Ein according to the energy signal Ein and the second average energy Eave(2).

Subsequently, the detecting result calculating module 106 is configured to provide a first difference signal, to generate a second difference signal according to a first difference signal and the second energy difference Ediff(2), and then to generate a third difference signal according to the second difference signal and the third energy difference Ediff(3). Furthermore, the first difference signal is predetermined. In this embodiment, the detecting result calculating module 106 generates the second difference signal and the third difference signal according to the equation (4) as follow:

$$\overline{Ediff} ( q ) = \frac{\overline{Ediff} ( q - 1 ) + Ediff ( q )}{2} \qquad ( 4 )$$

wherein E̅d̅i̅f̅f̅(q) denotes the qth difference signal, Ediff(q) denotes the qth energy difference of the qth period of the energy signal Ein, and the initial value of the discrete number q is 2. In this embodiment, the first difference signal E̅d̅i̅f̅f̅(1) is predetermined to the same as the second energy difference Ediff(2).

In one embodiment, the detecting result calculating module 106 is configured to compare the third difference signal E̅d̅i̅f̅f̅(3) with a default threshold corresponding to the third average signal E̅a̅v̅e̅(3), so as to generate the signal detecting result Sout. In this embodiment, when the third difference signal E̅d̅i̅f̅f̅(3) is equal to or smaller than the default threshold corresponding to the third average signal E̅a̅v̅e̅(3), the detecting result calculating module 106 determines that the input signal Sin is an effective signal; when the third difference signal E̅d̅i̅f̅f̅(3) is larger than the default threshold corresponding to the third average signal E̅a̅v̅e̅(3), the detecting result calculating module 106 determines that the input signal Sin is an ineffective signal.

For example, references are now made to FIGS. 2A, 2B and 2C. In this embodiment, each period of the illustrated energy signal Ein shown in FIGS. 2A, 2B and 2C has 16 symbols, and each symbol of the illustrated energy signal Ein shown in FIGS. 2A, 2B and 2C has 8 samples. In other words, the number of the samples of each period of the illustrated energy signal Ein, i.e., BlockSize, is 128. In one embodiment, when the number of the samples of each period of the illustrated energy signal Ein, i.e., BlockSize, is 128, the amplitude of the average energy Eave of each period of the energy signal Ein can be more evenly. Furthermore, the illustrated energy signal Ein has 5 period, i.e., from the first period T1 to the fifth period T5. For the purpose of understanding and convenience, the parameters disclosed herein are by examples, and the present disclosure is not limited hereto.

As shown in FIG. 2A, when the input signal Sin is a phase shift keying signal having a voltage value of 300 mV, the fifth average signal E̅a̅v̅e̅(5) equals to 24 and the fifth difference signal E̅d̅i̅f̅f̅(5) equals to 392. As shown in FIG. 2B, when the input signal Sin is a noise signal, the fifth average signal E̅a̅v̅e̅(5) equals to 16 and the fifth difference signal E̅d̅i̅f̅f̅(5) equals to 908. As shown in FIG. 2C, when the input signal Sin is a signal except the phase shift keying signal, e.g., a low frequency detecting signal, the fifth average signal E̅a̅v̅e̅(5) equals to 18 and the fifth difference signal E̅d̅i̅f̅f̅(5) equals to 851.

Subsequently, referring to FIG. 2D, FIG. 2D is an operating schematic diagram of the detecting result calculating module 106 of the signal detecting system 100 according to some embodiments of the present disclosure. As shown in FIG. 2D, each average signal corresponds to a default threshold. A dash line is shown in FIG. 2D for representing the corresponding relation between the average signal and the default threshold. In one embodiment, default threshold can be adjusted according to noise effect (that is, a practical threshold may be higher than the default threshold), and then the dash line represented the corresponding relation between the average signal and the default threshold should be correspondingly adjusted. For example, when the input signal Sin is a phase shift keying signal having a voltage value of 300 mV, the fifth difference signal E̅d̅i̅f̅f̅(5) of the input signal Sin equals to 392 and the fifth average signal E̅a̅v̅e̅(5) of the input signal Sin equals to 24 as shown in FIG. 2A. Therefore, the fifth average signal E̅a̅v̅e̅(5) of the input signal Sin which equals to 24 can be used as a basis to correspondingly obtain the default threshold which approximately equals to 460. Since the fifth difference signal E̅d̅i̅f̅f̅(5) of the input signal Sin which equals to 392 is smaller than the default threshold which approximately equals to 460, the input signal Sin having the energy signal Ein shown in FIG. 2A is determined as an effective signal.

As another example, when the input signal Sin is a noise signal, the fifth difference signal E̅d̅i̅f̅f̅(5) of the input signal Sin equals to 908 and the fifth average signal E̅a̅v̅e̅(5) of the input signal Sin equals to 16 as shown in FIG. 2B. Therefore, the fifth average signal E̅a̅v̅e̅(5) of the input signal Sin which equals to 16 can be used as a basis to correspondingly obtain the default threshold which approximately equals to 330. Since the fifth difference signal E̅d̅i̅f̅f̅(5) of the input signal Sin which equals to 908 is larger than the default threshold which approximately equals to 330, input signal Sin having the energy signal Ein shown in FIG. 2B is determined as an ineffective signal.

In one embodiment, as shown in FIG. 1, the signal detecting system 100 further includes a mixer 112, a low pass filter 114 and an energy calculating module 116. The low pass filter 114 is electrically connected to the mixer 112 and the energy calculating module 116, and the energy calculating module 116 is electrically connected to the average energy calculating module 102 and the energy difference calculating module 104. The mixer 112 is configured to receive an input signal Sin, and to shift the frequency of the input signal to generate a shifted signal. The low pass filter 114 is configured to receive and filter the shifted signal, and then the energy calculating module 116 is configured to generate the energy signal Ein according to the shifted signal which has been filtered through the low pass filter 114. For example, the order of the low pass filter 114 which relates to the amplitude and the ripple of the energy signal Ein can be set the same as the number of the samples of each symbol of the energy signal Ein. In this embodiment, each symbol of the energy signal Ein has 8 samples, so that the low pass filter 114 can be set as an eighth order low pass filter. Persons of ordinary skill in the art can modify the order of the low pass filter 114 according to their actual demands, and so the low pass filter 114 is not limited by such example.

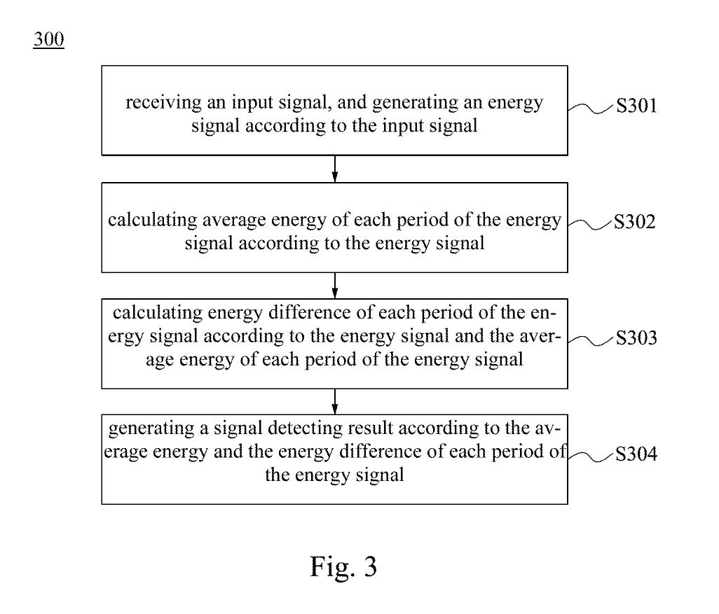

FIG. 3 is a flow chart of a signal detecting method 300 according to some embodiments of the present disclosure. In one embodiment, the signal detecting method 300 can be implemented by the signal detecting system 100, but the present disclosure in not limited hereto. For facilitating the understanding of the signal detecting method 300, the notations marked in the signal detecting system 100 are repeatedly used to illustrate the signal detecting method 300 as follows. As shown in FIG. 3, the signal detecting method 300 includes operations as follows:
S301: receiving an input signal Sin, and generating an energy signal Ein according to the input signal Sin;
S302: calculating average energy Eave of each period of the energy signal Ein according to the energy signal Ein;
S303: calculating energy difference Ediff of each period of the energy signal Ein according to the energy signal Ein and the average energy Eave of each period of the energy signal Ein; and
S304: generating a signal detecting result Sout according to the average energy Eave and the energy difference Ediff of each period of the energy signal Ein.

In one embodiment, referring to the operation S304, before the signal detecting result Sout is generated, the average signals and the difference signals are generated according to the average energy Eave of each period of the energy signal Ein and the energy difference Ediff of each period of the energy signal Ein. Subsequently, the average signals are compared with the difference signals to generate the signal detecting result Sout.

In another embodiment, the operation S302 is further executed as shown below. The first average energy Eave(1) of the first period T1 of the energy signal Ein, the second average energy Eave(2) of the second period T2 of the energy signal Ein and the third average energy Eave(3) of the third period T3 of the energy signal Ein are calculated according to the energy signal Ein. Subsequently, the operation S304 is further executed as shown below. The second average signal E̅a̅v̅e̅(2) is generated according to the predetermined first average signal E̅a̅v̅e̅(1) and the second average energy Eave(2), and then the third average signal E̅a̅v̅e̅(3) is generated according to the second average signal E̅a̅v̅e̅(2) and the third average energy Eave(3).

In further embodiment, the operation S303 is further executed as shown below. The second energy difference Ediff(2) of the second period T2 of the energy signal Ein is calculated according to the energy signal Ein and the first average energy Eave(1), and then the third energy difference Ediff(3) of the third period T3 of the energy signal Ein is calculated according to the energy signal Ein and the second average energy Eave(2). Furthermore, the first energy difference Ediff(1) of the first period T1 of the energy signal Ein is predetermined. Subsequently, the operation S304 is further executed as shown below. The second difference signal E̅d̅i̅f̅f̅(2) is generated according to the predetermined first difference signal E̅d̅i̅f̅f̅(1) and the second energy difference Ediff(2), and then the third difference signal E̅d̅i̅f̅f̅(3) is generated according to the second difference signal E̅d̅i̅f̅f̅(2) and the third energy difference Ediff(3).

In further embodiment, the operation 3304 is further executed as shown below. The third difference signal E̅d̅i̅f̅f̅(3) is compared with the default threshold corresponding to the third average signal E̅a̅v̅e̅(3) to generate the signal detecting result Sout. In this embodiment, when the third difference signal E̅d̅i̅f̅f̅(3) is equal to or smaller than the default threshold corresponding to the third average signal E̅a̅v̅e̅(3), the input signal Sin is determined as an effective signal; when the third difference signal E̅d̅i̅f̅f̅(3) is larger than the default threshold corresponding to the third average signal E̅a̅v̅e̅(3), the input signal Sin is determined as an ineffective signal.

As mentioned above, the signal detecting method and the signal detecting system in the present disclosure are configured to generate the energy signal according to the input signal, and to calculate the average energy and the energy difference of each period of the energy signal in advance. Subsequently, the signal detecting method and the signal detecting system in the present disclosure are further configured to generate the average signals and the difference signals according to the average energy and the energy difference of each period of the energy signal in advance, and to compare the average signals with the difference signals, so as to generate the signal detecting result. For example, the characteristics of the average signals and the difference signals of the effective signal are significantly different from that of the ineffective signals. e.g., noise signal. Therefore, the effective signals having the specific characteristics of the average signals and the difference signals now can be accurately detected, and the power consumption of the wireless communication devices can be significantly reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present invention cover modifications and variations of this present disclosure provided they fall within the scope of the following claims.

What is claimed is:

1. A signal detecting method, comprising:
receiving an input signal, and generating an energy signal in accordance with the input signal;
calculating average energy of each period of the energy signal in accordance with the energy signal;
calculating energy difference of each period of the energy signal in accordance with the energy signal and the average energy of each period of the energy signal; and
generating a signal detecting result in accordance with the average energy and the energy difference of each period of the energy signal.

2. The signal detecting method of claim 1, wherein generating the signal detecting result in accordance with the average energy and the energy difference of each period of the energy signal comprises:
generating average signals in accordance with the average energy of each period of the energy signal;
generating difference signals in accordance with the energy difference of each period of the energy signal; and
comparing the average signals with the difference signals to generate the signal detecting result.

3. The signal detecting method of claim 2, wherein calculating the average energy of each period of the energy signal in accordance with the energy signal comprises:
calculating first average energy of a first period of the energy signal in accordance with the energy signal;
calculating second average energy of a second period of the energy signal in accordance with the energy signal, wherein the second period is adjacent to the first period; and
calculating third average energy of a third period of the energy signal in accordance with the energy signal, wherein the third period is adjacent to the second period.

4. The signal detecting method of claim 3, wherein generating the average signals in accordance with the average energy of each period of the energy signal comprises:
providing a first average signal;
generating a second average signal in accordance with a first average signal and the second average energy; and
generating a third average signal in accordance with the second average signal and the third average energy.

5. The signal detecting method of claim 4, wherein calculating the energy difference of each period of the energy signal in accordance with the energy signal and the average energy of each period of the energy signal comprises:
providing a first energy difference;
calculating a second energy difference of the second period of the energy signal in accordance with the energy signal and the first average energy;
calculating a third energy difference of the third period of the energy signal in accordance with the energy signal and the second average energy.

6. The signal detecting method of claim 5, wherein generating the difference signals in accordance with the energy difference of each period of the energy signal comprises:
providing a first difference signal;
generating a second difference signal in accordance with the first difference signal and the second energy difference;
generating a third difference signal in accordance with the second difference signal and the third energy difference.

7. The signal detecting method of claim 6, wherein comparing the average signals and the difference signals to generate the signal detecting result comprises:
comparing the third difference signal with a default threshold corresponding to the third average signal to generate the signal detecting result.

8. The signal detecting method of claim 7, wherein when the third difference signal is equal to or smaller than the default threshold corresponding to the third average signal, the input signal is determined as an effective signal; when the third difference signal is larger than the default threshold corresponding to the third average signal, the input signal is determined as an ineffective signal.

9. A signal detecting system, comprising:
an average energy calculating module, configured to calculate average energy of each period of an energy signal in accordance with the energy signal;
an energy difference calculating module, electrically connected to the average energy calculating module, and configured to calculate energy difference of each period of the energy signal in accordance with the energy signal and the average energy of each period of the energy signal; and
a detecting result calculating module, electrically connected to the average energy calculating module and the energy difference calculating module, and configured to generate a signal detecting result in accordance with the average energy and the energy difference of each period of the energy signal.

10. The signal detecting system of claim 9, further comprising;
a mixer, configured to receive an input signal, and to shift the frequency of the input signal to generate a shifted signal; and
a low pass filter, electrically connected to the mixer, and configured to filter the shifted signal to generate the energy signal.

11. The signal detecting system of claim 9, wherein the detecting result calculating module is configured to generate average signals in accordance with the average energy of each period of the energy signal, to generate difference signals in accordance with the energy difference of each period of the energy signal, and to compare the average signals with the difference signals to generate the signal detecting result.

12. The signal detecting system of claim 11, wherein the average energy calculating module is configured to calculate first average energy of a first period of the energy signal, second average energy of a second period of the energy signal, and third average energy of a third period of the energy signal in accordance with the energy signal;
wherein the second period is adjacent to the first period, and the third period is adjacent to the second period.

13. The signal detecting system of claim 12, wherein the detecting result calculating module is configured to provide a first average signal, to generate a second average signal in accordance with a first average signal and the second average energy, and to generate a third average signal in accordance with the second average signal and the third average energy, wherein the first average signal is predetermined.

14. The signal detecting system of claim 13, wherein the energy difference calculating module is configured to provide a first energy difference, to calculate a second energy difference of the second period of the energy signal in accordance with the energy signal and the first average energy, and to calculate a third energy difference of the third period of the energy signal in accordance with the energy signal and the second average energy, wherein the first energy difference is predetermined.

15. The signal detecting system of claim 14, wherein the detecting result calculating module is configured to provide a first difference signal, to generate a second difference signal in accordance with a first difference signal and the second energy difference, and to generate a third difference signal in accordance with the second difference signal and the third energy difference, wherein the first difference signal is predetermined.

16. The signal detecting system of claim 15, wherein the detecting result calculating module is configured to compare the third difference signal with a default threshold corresponding to the third average signal to generate the signal detecting result.

17. The signal detecting system of claim 16, wherein when the third difference signal is equal to or smaller than the default threshold corresponding to the third average signal, the detecting result calculating module determines that the input signal is an effective signal; when the third difference signal is larger than the default threshold corresponding to the third average signal, the detecting result calculating module determines that the input signal is an ineffective signal.
